(19) United States
(12) Patent Application Publication
(10) Pub. No.: US 2015/0004787 A1
(43) Pub. Date: Jan. 1, 2015

(54) Sapphire Pad Conditioner

(71) Applicant: Taiwan Semiconductor Manufacturing Company, Ltd., Hsin-Chu (TW)

(72) Inventors: Jung-Lung Hung, Hsinchu City (TW); Chi-Hao Huang, Zhunan Township (TW); Jaw-Lih Shih, Jhudong Township (TW); Hong-Hsing Chou, Jhubei City (TW); Yeh-Chieh Wang, Hsinchu City (TW)

(21) Appl. No.: 13/930,404

(22) Filed: Jun. 28, 2013

(51) Int. Cl. H01L 21/306; B24B 53/12; B24D 18/00; B24B 53/017

(52) U.S. Cl. CPC H01L 21/30625; B24B 53/017; B24B 53/12; B24D 18/00
USPC 438/692; 451/443; 451/56; 51/309

(57) ABSTRACT

A sapphire pad conditioner includes a sapphire substrate having multiple protrusions on a surface and a holder arranged to hold the sapphire substrate. The sapphire substrate is used for conditioning a chemical mechanical planarization (CMP) pad.

### INCORPORATION BY REFERENCE

A journal article titled “Chlorine-Based ICP Etching for Improving the Luminance Efficiency in Nitride LEDs,” by H. Ogiya, et al., published in CS MANTECH Conference in 2012, Boston, Mass., USA, also submitted with IDS of this application, is incorporated herein by reference in its entirety.

### TECHNICAL FIELD

The present disclosure relates generally to an integrated circuit and more particularly a pad conditioner.

### BACKGROUND

Chemical mechanical planarization (CMP) uses the rough surface of a CMP pad for polishing a wafer to obtain a global planarization of the wafer surface. The roughness of the CMP pad surface affects the removal rate. A pad conditioner used for conditioning the CMP pad removes the accumulated debris and byproduct during the CMP polishing process and also (re-) makes the CMP pad surface rough. However, some pad conditioners have issues with corrosion of bonding material in acidity or alkalinity environment that may lead to some abrasive elements loss.

### BRIEF DESCRIPTION OF THE DRAWINGS

Reference is now made to the following descriptions taken in conjunction with the accompanying drawings, in which:

FIGS. 1A- 1B are cross section views of an exemplary sapphire pad conditioner according to some embodiments;

FIG. 1C is a top view of the exemplary sapphire pad conditioner in FIG. 1A with a height distribution map according to some embodiments;

FIGS. 2A-2E are intermediate steps of fabricating the exemplary sapphire pad conditioner in FIG. 1A according to some embodiments;

FIG. 3 is a schematic diagram showing a pad conditioning and chemical mechanical planarization (CMP) set up; and

FIG. 4 is a flowchart of a method of pad conditioning and chemical mechanical planarization (CMP) using the set up in FIG. 3 according to some embodiments.

### DETAILED DESCRIPTION

The making and using of various embodiments are discussed in detail below. It should be appreciated, however, that the present disclosure provides many applicable inventive concepts that can be embodied in a wide variety of specific contexts. The specific embodiments discussed are merely illustrative of specific ways to make and use, and do not limit the scope of the disclosure.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

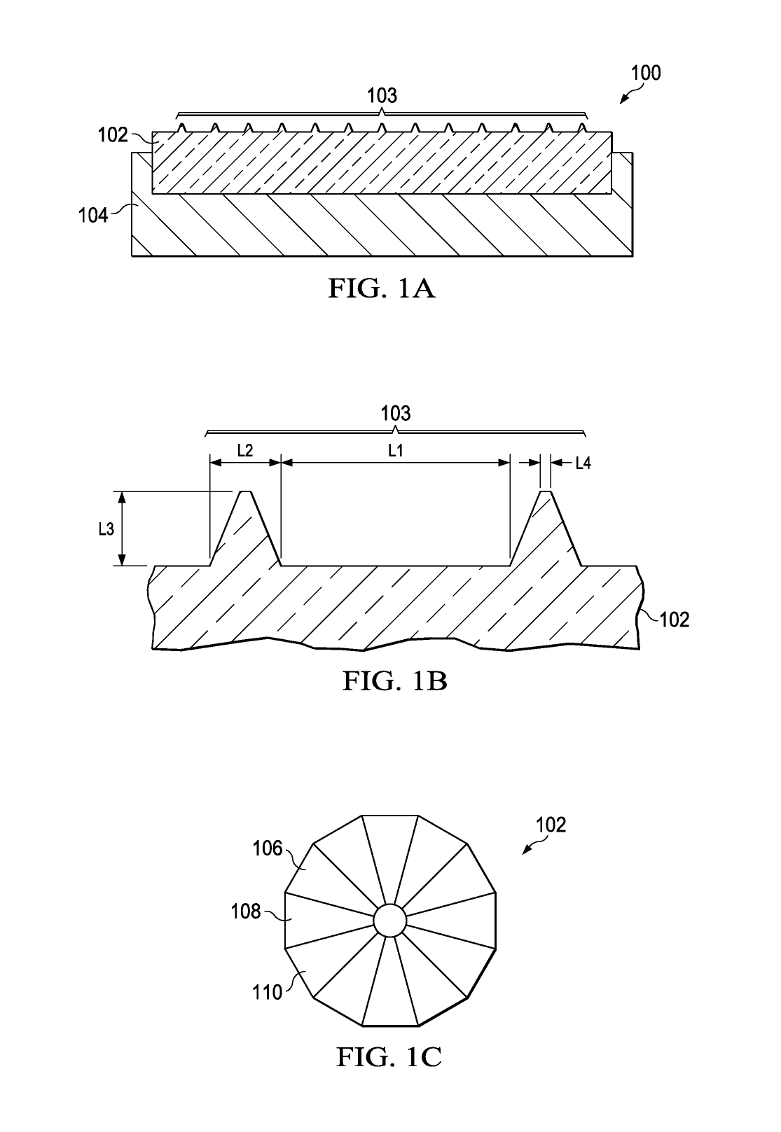

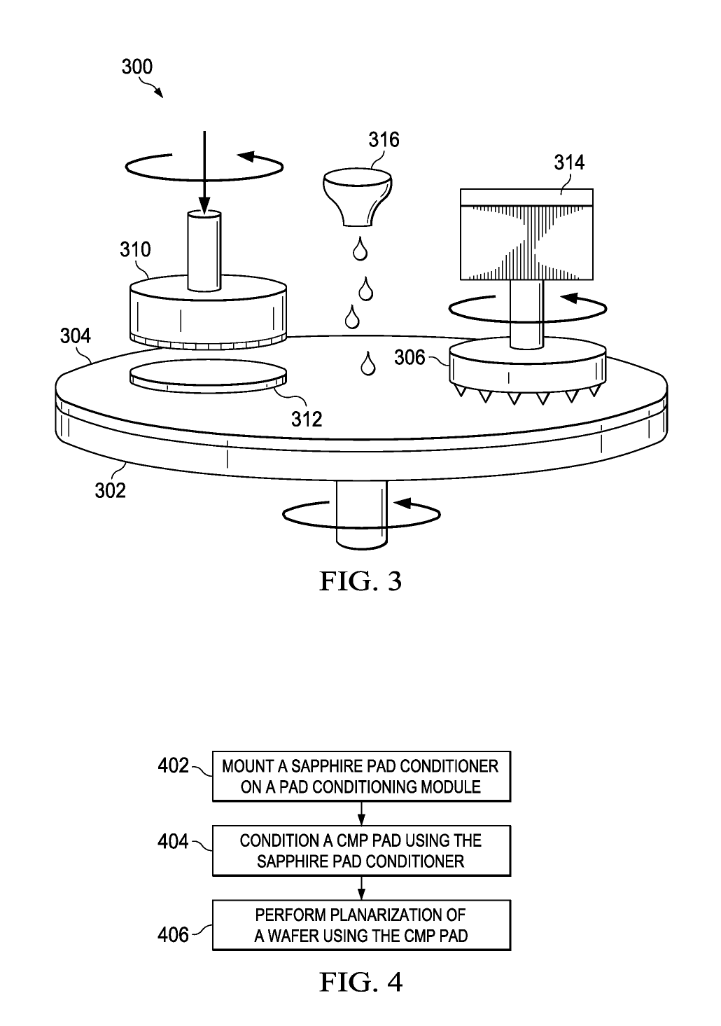

FIGS. 1A-1B are cross section views of an exemplary sapphire pad conditioner 100 according to some embodiments. The sapphire pad conditioner 100 includes a sapphire substrate 102 having multiple protrusions 103 on its surface. The sapphire substrate 102 is used for conditioning a chemical mechanical planarization (CMP) pad (such as 304 shown in FIG. 3). A holder 104 is arranged to hold the sapphire substrate 102 during the CMP process.

The sapphire material has a hardness of 9 in Mohs scale, which is comparable to an industrial diamond's hardness of 9.25. The sapphire substrate 102 is a patterned sapphire substrate (PSS) with the multiple protrusions 103. In some embodiments, the sapphire substrate 102 has a thickness of about 3 mm and has a disk shape with a diameter of about 3.8 inches.

In some embodiments, the holder 104 comprises stainless steel and has a thickness of about 5 mm with a 4 inch diameter in a disk shape. The stainless steel material is resistant to corrosion, rust, or stain. In some embodiments, the sapphire substrate 102 can be placed about 2 mm into the indentation space formed on the holder 104. The size of the sapphire pad conditioner 100 can be different depending on applications.

The multiple protrusions 103 are shown in a close up diagram in FIG. 1B. In some embodiments, the protrusions 103 have a spacing L1 ranging from about 400 μm to about 700 μm in between adjacent protrusions 103. In some embodiments, the protrusions 103 have a width L2 ranging from about 100 μm to about 180 μm, a height L3 ranging from about 50 μm to about 80 μm, and a relatively flat top width L4 ranging from about 2 μm to about 5 μm.

In some embodiments, the protrusions 103 have different heights depending on the location on the sapphire substrate 102. For example, FIG. 1C is a top view of the exemplary sapphire pad conditioner in FIG. 1A with a height distribution map according to some embodiments. The protrusions 103 in a first circular sector 106 have a first height that is different from a second height of the protrusions 103 in a second circular sector 108.

In one example, the protrusions 103 in sections 106 have a protrusion height L3 of about 50 μm, the protrusions 103 in sections 108 have a protrusion height L3 of about 60 μm, and the protrusions 103 in sections 110 have a protrusion height L3 of about 80 μm. In other embodiments, any different mapping shape or scheme can be used for different protrusion height distributions in a predetermined pattern.

The precision of a PSS process for the sapphire substrate 102 is less than 1 μm, compared to a diamond disk leveling precision of about 5 μm-10 μm. Better uniformity and precision can be obtained for the protrusions 103 on the sapphire substrate 102 compared to some other pad conditioners.

Because the protrusions 103 are patterned on the sapphire substrate 102 directly for the sapphire pad conditioner 100, the protrusions 103 are less likely to break off during pad conditioning, which causes a macro scratch issue during a CMP process. In comparison, diamond pieces held together by bonding material are more likely to break off to cause a macro scratch issue during a CMP process. Thus, the sapphire pad conditioner 100 needs less preventive maintenance. With the reduced scratch issue and preventive maintenance, the CMP process efficiency and yield are improved for the sapphire pad conditioner 100.

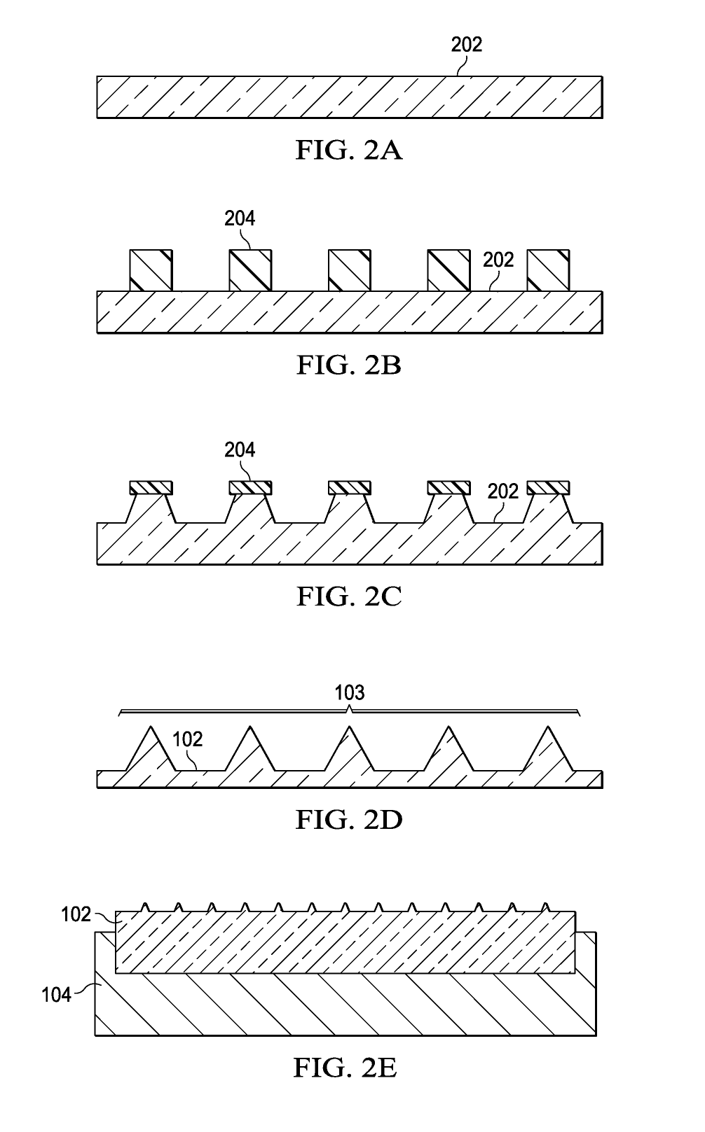

FIGS. 2A-2E are intermediate steps of fabricating the exemplary sapphire pad conditioner 100 in FIG. 1A according to some embodiments. In FIG. 2A, a bare sapphire substrate (or wafer) 202 is shown. In FIG. 2B, a photoresist layer 204 is deposited and patterned over the bare sapphire substrate 202. For example, the photoresist layer 204 can be deposited on the sapphire substrate 202 by coating and patterned by photolithography processes such as aligning a photo mask over the photoresist layer 204 and exposing the photoresist layer 204 to an ultraviolet light.

In FIG. 2C, the sapphire substrate is etched and patterned so that the etched sapphire substrate 102 in FIG. 2D has multiple protrusions 103 on its surface. For example, a wet etching technique according to a PSS process known in the art can be used.

In FIG. 2E, the sapphire substrate 102 is mounted on a holder that is arranged to hold the sapphire substrate 102 while the sapphire substrate 102 is used for pad conditioning in a chemical mechanical planarization (CMP) process. The holder 104 comprises stainless steel in some embodiments.

FIG. 3 is a schematic diagram showing a pad conditioning and chemical mechanical planarization (CMP) set up. In FIG. 3, a CMP pad 304 is mounted on a platen 302 that is rotated during a CMP process. A sapphire pad conditioner 306 including the sapphire substrate 102 and the holder 104 in FIG. 1A is mounted on a rotator of a pad conditioning module 314. (The sapphire pad substrate 102 has multiple protrusions 103 on its surface as shown in FIG. 1A.) A carrier 310 can hold the wafer 312 and rotate the wafer 312 during the CMP process. A slurry supply 316 provides slurry during the CMP process.

FIG. 4 is a flowchart of a method of pad conditioning and chemical mechanical planarization (CMP) using the set up in FIG. 3 according to some embodiments. At step 402, a sapphire pad conditioner 306 is mounted on the pad conditioning module 314. For example, the sapphire pad conditioner 306 can be fixed to a rotator of the pad conditioning module 314. The sapphire pad conditioner 306 includes the sapphire substrate 102 that has multiple protrusions 103 on a surface and the holder 104 as shown in FIG. 1A. The holder 104 comprises stainless steel in some embodiments.

At step 404, the CMP pad 304 is conditioned using the sapphire pad conditioner 306. For example, the CMP pad 304 is rotated by the platen 302, the sapphire pad conditioner 306 is rotated by the pad conditioning module 314, and the sapphire pad conditioner 306 is lowered towards the CMP pad 304 for conditioning to make the surface of the CMP pad 304 rough and clean of debris and byproducts from a previous CMP process.

At step 406, planarization of the wafer 312 is performed using the CMP pad 304. For example, the CMP pad 304 mounted on the platen 302 is rotated, the wafer 312 mounted on the carrier 310 is rotated and lowered towards the CMP pad 304, and slurry supply 316 provides slurry for the CMP process. With the sapphire pad conditioner 306 that includes the sapphire substrate 102, the CMP efficiency and yield are improved due to reduced scratch issue from debris and broken pad conditioner pieces.

According to some embodiments, a sapphire pad conditioner includes a sapphire substrate having multiple protrusions on a surface and a holder arranged to hold the sapphire substrate. The sapphire substrate is used for conditioning a chemical mechanical planarization (CMP) pad.

According to some embodiments, a method includes depositing a photoresist layer on a sapphire substrate. The photoresist layer is patterned. The sapphire substrate is etched so that the sapphire substrate has multiple protrusions on a surface. The sapphire substrate is mounted on a holder. The holder is arranged to hold the sapphire substrate while the sapphire substrate is used for pad conditioning in a chemical mechanical planarization (CMP) process.

According to some embodiments, a method includes mounting a sapphire pad conditioner on a pad conditioning module. The sapphire pad conditioner has multiple protrusions on a surface. A chemical mechanical planarization (CMP) pad is conditioned using the sapphire pad conditioner.

A skilled person in the art will appreciate that there can be many embodiment variations of this disclosure. Although the embodiments and their features have been described in detail, it should be understood that various changes, substitutions and alterations can be made herein without departing from the spirit and scope of the embodiments. Moreover, the scope of the present application is not intended to be limited to the particular embodiments of the process, machine, manufacture, and composition of matter, means, methods and steps described in the specification. As one of ordinary skill in the art will readily appreciate from the disclosed embodiments, processes, machines, manufacture, compositions of matter, means, methods, or steps, presently existing or later to be developed, that perform substantially the same function or achieve substantially the same result as the corresponding embodiments described herein may be utilized according to the present disclosure.

The above method embodiment shows exemplary steps, but they are not necessarily required to be performed in the order shown. Steps may be added, replaced, changed order, and/or eliminated as appropriate, in accordance with the spirit and scope of embodiment of the disclosure. Embodiments that combine different claims and/or different embodiments are within the scope of the disclosure and will be apparent to those skilled in the art after reviewing this disclosure.

What is claimed is:

1. A sapphire pad conditioner, comprising:
a sapphire substrate having multiple protrusions on a surface; and
a holder arranged to hold the sapphire substrate, wherein the sapphire substrate is configured to be used for conditioning a chemical mechanical planarization (CMP) pad.

2. The sapphire pad conditioner of claim 1, wherein the multiple protrusions have different heights.

3. The sapphire pad conditioner of claim 2, wherein the multiple protrusions having different heights are distributed in a predetermined pattern.

4. The sapphire pad conditioner of claim 3, wherein the protrusions in a first circular sector have a first height that is different from a second height of the protrusions in a second circular sector.

5. The sapphire pad conditioner of claim 1, wherein the holder comprises stainless steel.

6. The sapphire pad conditioner of claim 1, wherein the multiple protrusions have a height ranging from about 50 μm to about 80 μm.

7. The sapphire pad conditioner of claim 1, wherein the multiple protrusions have a width ranging from about 100 μm to about 180 μm.

8. The sapphire pad conditioner of claim 1, wherein the multiple protrusions have a spacing ranging from about 400 μm to about 700 μm in between.

9. The sapphire pad conditioner of claim 1, wherein the multiple protrusions have a relatively flat top width ranging from about 2 μm to about 5 μm.

10. A method, comprising:
depositing a photoresist layer on a sapphire substrate;
patterning the photoresist layer;
etching the sapphire substrate so that the sapphire substrate has multiple protrusions on a surface; and
mounting the sapphire substrate on a holder, wherein the holder is arranged to hold the sapphire substrate while the sapphire substrate is configured to be used for pad conditioning in a chemical mechanical planarization (CMP) process.

11. The method of claim 10, wherein patterning the photoresist layer comprises:
aligning a photo mask over the photoresist layer; and
exposing the photoresist layer to an ultraviolet light.

12. The method of claim 10, wherein the multiple protrusions have different heights.

13. The method of claim 12, wherein the multiple protrusions having different heights are distributed in a predetermined pattern.

14. The method of claim 13, wherein the protrusions in a first circular sector have a first height that is different from a second height of the protrusions in a second circular sector.

15. The method of claim 10, wherein the holder comprises stainless steel.

16. A method, comprising:
mounting a sapphire pad conditioner on a pad conditioning module, wherein the sapphire pad conditioner has multiple protrusions on a surface; and
conditioning a chemical mechanical planarization (CMP) pad using the sapphire pad conditioner.

17. The method of claim 16, wherein the conditioning comprises:
rotating the CMP pad;
rotating the sapphire pad conditioner; and
lowering the sapphire pad conditioner towards the CMP pad.

18. The method of claim 16, wherein the mounting comprises fixing the sapphire pad conditioner to a rotator of the pad conditioning module.

19. The method of claim 16, wherein the wherein the multiple protrusions have different heights.

20. The method of claim 16, further comprising performing planarization of a wafer using the CMP pad.
